(19) United States
(12) Patent Application Publication
(10) Pub. No.: US 2024/0387400 A1
(43) Pub. Date: Nov. 21, 2024

(54) SEMICONDUCTOR DEVICE AND METHOD FOR MAKING THE SAME

(71) Applicant: STATS ChipPAC Pte. Ltd., Singapore (SG)

(72) Inventors: JiSeon LEE, Incheon (KR); BumRyul MAENG, Incheon (KR); HyunKyu LEE, Incheon (KR)

(21) Appl. No.: 18/646,903

(22) Filed: Apr. 26, 2024

(30) Foreign Application Priority Data
May 17, 2023 (CN) 202310559264.X

(51) Int. Cl. H01L 23/552; H01L 21/56; H01L 23/14; H01L 23/31; H01L 23/528

(52) U.S. Cl. CPC H01L 23/552; H01L 21/561; H01L 23/14; H01L 23/3157; H01L 23/5283

(57) ABSTRACT

A semiconductor device and a method for making the same are provided. The method includes: providing a package including: a substrate having a front substrate surface and a back substrate surface, wherein the substrate includes a plurality of singulation areas separating the substrate into a plurality substrate units; a plurality of first electronic components mounted on the front substrate surface and within the plurality substrate units, respectively; and an encapsulant formed on the front substrate surface and encapsulating the plurality of first electronic components; forming a plurality of trenches at the plurality of singulation areas, respectively, wherein each of the plurality of trenches has a first portion extending through the encapsulant and a second portion extending through the encapsulant and the substrate; and forming an EMI shield to cover the encapsulant and lateral surfaces of the plurality of substrate units exposed by the second portions of the plurality of trenches.

### TECHNICAL FIELD

The present application generally relates to semiconductor technology, and more particularly, to a semiconductor device and a method for making the same.

### BACKGROUND OF THE INVENTION

The semiconductor industry is constantly faced with complex integration challenges as consumers want their electronics to be smaller, faster and higher performance with more and more functionalities packed into a single device. One of the solutions is System-in-Package (SiP). The SiP is a functional electronic system or sub-system that includes in a single package two or more heterogeneous semiconductor dice, such as a logic chip, a memory, integrated passive devices, radio frequency (RF) filters, sensors, heat sinks, or antennas. To enhance manufacturing throughput, some manufacturing processes of the SiPs can be performed at strip level. That is, the manufacturing processes of the SiPs are performed on multiple substrate units of a substrate strip in parallel. However, the conventional strip-level manufacturing method is complex, resulting in an excess cost.

Therefore, a need exists for further improvement to strip-level manufacturing method for SiPs.

### SUMMARY OF THE INVENTION

An objective of the present application is to provide a method for making a semiconductor device with simplified processes.

According to an aspect of embodiments of the present application, a method for making a semiconductor device. The method may include: providing a package including: a substrate having a front substrate surface and a back substrate surface opposite to the front substrate surface, wherein the substrate includes a plurality of singulation areas separating the substrate into a plurality substrate units; a plurality of first electronic components mounted on the front substrate surface and within the plurality substrate units, respectively; and an encapsulant formed on front substrate surface and encapsulating the plurality of first electronic components; forming a plurality of trenches at the plurality of singulation areas, respectively, wherein each of the plurality of trenches has a first portion extending through the encapsulant and a second portion extending through the encapsulant and the substrate; and forming an electromagnetic interference (EMI) shield to cover the encapsulant and lateral surfaces of the plurality of substrate units exposed by the second portions of the plurality of trenches.

According to another aspect of embodiments of the present application, a semiconductor device is provided. The semiconductor device may include: a substrate having a front substrate surface and a back substrate surface opposite to the front substrate surface; a first electronic component mounted on the front substrate surface; an encapsulant formed on the front substrate surface and encapsulating the first electronic component; and an electromagnetic interference (EMI) shield having a top portion covering a top surface of the encapsulant, a first lateral portion covering a first lateral surface of the encapsulant and a first lateral surface of the substrate, and a second lateral portion covering a second lateral surface of the encapsulant.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A and 1B to FIGS. 4A and 4B, and FIGS. 5 to 7 are top views or cross-sectional view illustrating various steps of a method for making a semiconductor device according to an embodiment of the present application.

FIG. 8 is a cross-sectional view illustrating a semiconductor device according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

System-in-Package (SiP) may integrate therein two or more heterogeneous semiconductor dice or other types of electronic components, and may use Double Side Molding (DSM) technology to further shrink its overall package size. However, it is hard to perform all manufacturing processes of the SiP at strip level.

For example, a SiP module for a wearable device may include a radio frequency (RF) chip mounted on a front surface of a substrate, and one or more connectors or clips mounted on a back surface of the substrate. An electromagnetic interference (EMI) shield is usually formed on an encapsulant covering the RF chip and lateral surfaces of the substrate. In a case that the connectors or clips are mounted on the substrate before forming the EMI shield, the connectors or clips may interfere with the processing by the equipment for forming the EMI shield, as a height of the connectors or clips is usually higher than conventional semiconductor dice. Thus, in a conventional method, a substrate strip of SiP modules usually has to be singulated into individual substrate units after mounting electronic components (including RF chips) on a front surface of the substrate strip and forming an encapsulant thereon. Afterwards, an EMI shield is formed on each substrate unit to cover the encapsulant and lateral surfaces of the substrate unit, and then one or more connectors or clips are mounted on a back surface of the substrate unit. That is, the processes for forming the EMI shield and mounting the connectors or clips cannot be performed at strip level, resulting in lower units-per-hour (UPH) value, higher cost, and larger manufacturing deviation.

To address at least one of the above problems, in the embodiments of the present application, a method for forming a semiconductor device is provided. In the method, a plurality of electronic components are mounted on a front surface of a substrate strip, and an encapsulant is formed to encapsulate the plurality of electronic components. Then, a plurality of trenches are formed at a plurality of singulation areas of the substrate strip. Each trench may have a first portion extending through the encapsulant and a second portion extending through the encapsulant and the substrate strip. Afterwards, an EMI shield is formed to cover the encapsulant and a lateral surface of the substrate strip exposed by the second portions of the plurality of trenches, and one or more connectors or clips is mounted on a back surface of the substrate strip. That is, the method of the present application allows forming the EMI shield and mounting the connectors or clips at strip level, such that the entire time for processing can be reduced. As multiple semiconductor devices can be simultaneously formed at strip level, a deviation in the devices due to the manufacturing process can be reduced.

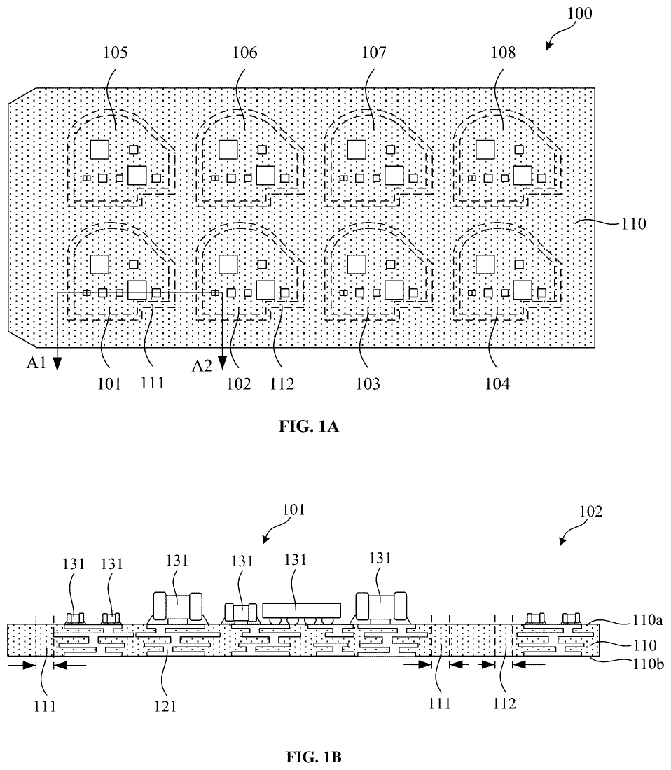

Referring to FIGS. 1A and 1B to FIGS. 4A and 4B, and FIGS. 5 to 7, top views and cross-sectional views illustrating various steps of a method for making a semiconductor device are shown.

Referring to FIGS. 1A and 1B, a package 100 is provided. FIG. 1A is a top view of the package 100, and FIG. 1B is a cross sectional view of the package 100 along a section line Al-A2 shown in FIG. 1A. The package 100 includes a substrate 110 and a plurality of first electronic components mounted on the substrate 110.

Specifically, the substrate 110 can provide support and connectivity for electronic components and devices mounted thereon. By way of example, the substrate 110 may include a printed circuit board (PCB), a carrier substrate, a semiconductor substrate with electrical interconnections, or a ceramic substrate. However, the substrate 110 is not to be limited to these examples. In other examples, the substrate 110 may include a laminate interposer, a strip interposer, a leadframe, or other suitable substrates.

To enhance manufacturing throughput, the substrate 110 may include a plurality of predefined substrate units, such as the substrate units 101 to 108 shown in FIG. 1A, thereby allowing some manufacturing processes to be performed on all the substrate units 101 to 108 in parallel. In the example shown in FIG. 1A, each of the substrate units 101 to 108 may have an irregular shape for use in a wearable device. In some other embodiments, the substrate units may have a square shape, a rectangular shape, a circular shape, or other shapes as desired. Further, in the example shown in FIG. 1A, the substrate units 101 to 108 are arranged in a two-dimensional array. However, the present application is not limited thereto. In some other embodiments, the substrate units may be arranged in a strip manner. That is, the substrate units can be arranged sequentially in a row.

The substrate 110 further includes a plurality of singulation areas, and the substrate units 101 to 108 are separated from each other by the plurality of singulation areas. In some examples, the singulation areas can provide respective cutting areas to singulate the substrate 110 into individual substrate units. In some embodiments, each singulation area may include a closed track enclosing a predefined substrate unit. For example, the substrate unit 101 is enclosed by a singulation area 111, and the substrate units 102 is enclosed by a singulation area 112.

For ease of description, the following configurations or manufacturing processes are primarily described with reference to the substrate unit 101 and related components, although the configurations or manufacturing processes can be similarly applied to or performed on other substrate units and related components.

As shown in FIG. 1B, the substrate unit 101 may include a plurality of interconnection structures 121. The interconnection structures 121 can provide connectivity for electronic components mounted on the substrate unit 101. The interconnection structures 121 may define pads, traces and plugs through which electrical signals or voltages can be distributed horizontally and vertically across the substrate unit 101. For example, as shown in FIG. 1B, the interconnection structures 121 may provide a plurality of contact pads on a front surface 110a and a back surface 110b of the substrate 110.

It could be understood that the scope of this application is not limited to the example shown in FIG. 1A. In some other embodiments, the substrate 110 may include more (for example, >8) or less (for example, <8) substrate units according to actual needs.

Continuing referring to FIGS. 1A and 1B, a plurality of first electronic components are mounted on the front substrate surface 110a and within the plurality substrate units 101 to 108 respectively. Taking the substrate unit 101 as an example, multiple first electronic components 131 are mounted on the front surface 110a of the substrate 110.

The first electronic components 131 can be mounted on the front surface 110a of the substrate 110 by flip-chip bonding or other suitable surface mounting techniques. For example, solder paste may be deposited or printed onto contact pads where the first electronic components 131 may be surface mounted. Then, the first electronic components 131 may be placed on the front surface 110a of the substrate 110 with terminals or contacts of the first electronic components 131 in contact with and over the solder paste. The solder paste may then be reflowed to mechanically and electrically couple the first electronic components 131 to the contact pads on the front surface 110a of the substrate 110.

The first electronic components 131 may include any of a variety of types of semiconductor dice, semiconductor packages, or discrete devices. For example, the first electronic components 131 may include a digital signal processor (DSP), a microcontroller, a microprocessor, a network processor, a power management processor, an audio processor, a video processor, an RF circuit, a wireless baseband system on chip (SoC) processor, a sensor, a memory controller, a memory device, an application specific integrated circuit (ASIC), etc.

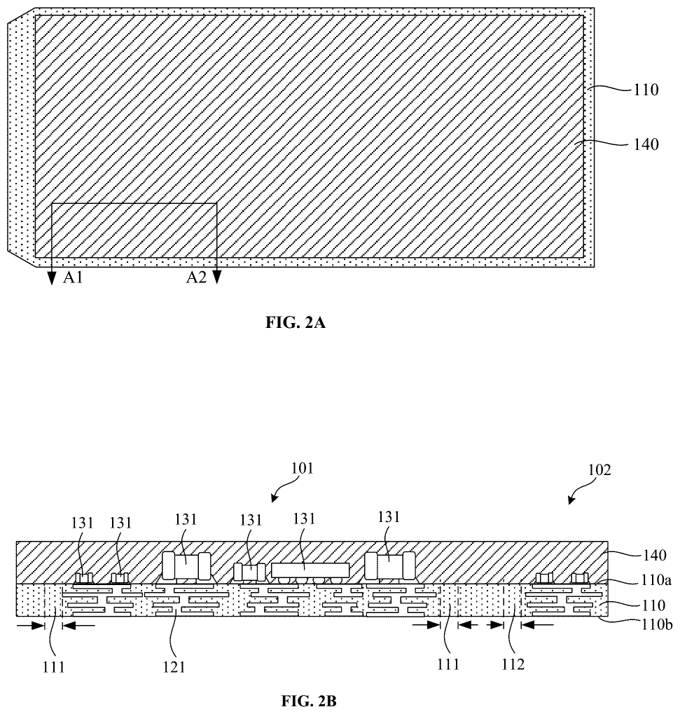

Afterwards, referring to FIGS. 2A and 2B, an encapsulant 140 is formed on the front surface 110a of the substrate 110 to encapsulate the plurality of first electronic components (including the multiple first electronic components 131). FIG. 2A is a top view of the package after the encapsulant 140 is formed, and FIG. 2B is a cross sectional view of the package along the section line A1-A2 shown in FIG. 2A.

In some embodiments, the encapsulant 140 may be formed on the front surface 110a of the substrate 110 using a molding process such as a compression molding process or an injection molding process. In some other embodiments, the encapsulant 140 may be formed using paste printing, transfer molding, liquid encapsulant molding, vacuum lamination, spin coating, or other suitable processes. The encapsulant 140 may be made of a polymer composite material, such as epoxy resin with filler, epoxy acrylate with filler, or polymer with proper filler, but the scope of this application is not limited thereto. In some examples, the encapsulant 140 may be planarized, if desired. The encapsulant 140 can provide mechanical protection, environmental protection, and a hermetic seal for the plurality of first electronic components mounted on the substrate 110.

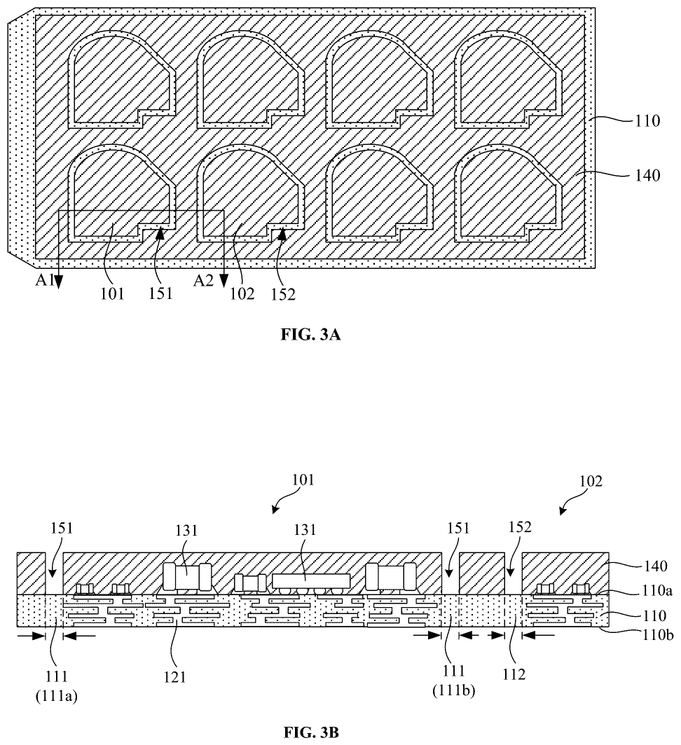

Afterwards, referring to FIGS. 3A and 3B, some portions of the encapsulant 140 at the plurality of singulation areas are removed to form a plurality of encapsulant trenches. The plurality of encapsulant trenches may expose the front surface 110a of the substrate 110. FIG. 3A is a top view of the package after the encapsulant trenches are formed, and FIG. 3B is a cross sectional view of the package along the section line A1-A2 shown in FIG. 3A.

For example, a portion of the encapsulant 140 at the singulation area 111 is removed to form an encapsulant trench 151, and a portion of the encapsulant 140 at the singulation area 112 is removed to form an encapsulant trench 152. Continuing taking the substrate unit 101 as an example, a laser ablation process may be employed to form the encapsulant trench 151 in the encapsulant 140. The laser ablation technique can accurately control a shape and/or a depth of the encapsulant trench 151 to be formed. However, the present application is not limited thereto. In other embodiments, the encapsulant trench 151 may be formed by a saw blade, a dry or wet etching process, or any other process known in the art so long as the encapsulant material can be removed as desired. In some other embodiments, after forming the encapsulant trenches, a cleaning process for removing residuals of the encapsulant material at the trenches may further be performed.

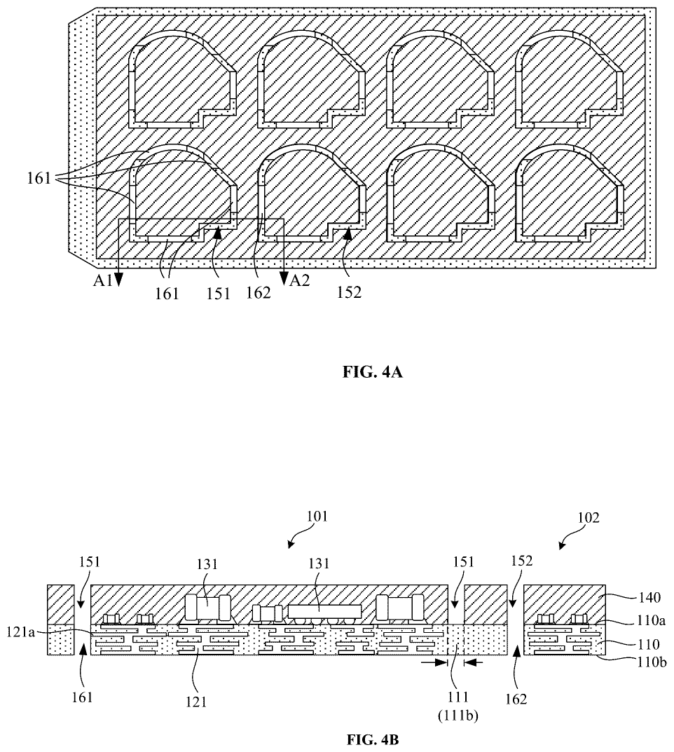

Afterwards, referring to FIGS. 4A and 4B, some portions of the substrate exposed by the plurality of encapsulant trenches are removed to form a plurality of substrate trenches. FIG. 4A is a top view of the package after the substrate trenches are formed, and FIG. 4B is a cross sectional view of the package along the section line A1-A2 shown in FIG. 4A.

Taking the substrate unit 101 as an example and referring to FIGS. 3A and 3B and FIGS. 4A and 4B, some portions 111a of the singulation area 111 enclosing the substrate unit 101 are removed to form multiple substrate trenches 161, and the remaining portions 111b of the singulation area 111, which are not removed, can serve as a support and connection to maintain the integrity of the substrate 110, allowing subsequent processes to be performed at strip level on the substrate 110, rather than being performed on individual substrate units. In some embodiments, an area of the substrate trenches 161 may account for 10% to 90% (for example, 20%, 30%, 40%, 50%, 60%, 70%, or 80%) of an area of the singulation area 111. In a preferred embodiment, the remaining portions 111b may account for less than 30%, or optionally 10% to 30%, of an area of the singulation area 111. In this way, the remaining portions 111b may maintain the integrity of the substrate 110 and allow for subsequent detachment of the substrate units, as will described below.

In some embodiments, a laser cutting process may be employed to form the substrate trenches 161 in the substrate 110. However, the present application is not limited thereto. In other embodiments, the substrate trenches 161 may be formed by a saw blading process, an etching process, or any other process known in the art so long as the substrate material can be removed.

As shown in FIGS. 4A and 4B, after the two-step laser ablation and laser cutting processes, a plurality of trenches are formed at the plurality of singulation areas, respectively. Each of the plurality of trenches may have a first portion extending through the encapsulant 140 and a second portion extending through the encapsulant 140 and the substrate 110. For example, the trench formed at the singulation area 111 may include a first portion consisted of a portion of the encapsulant trench 151 above the remaining portions 111b of the singulation area 111, which only extends through the encapsulant 140, and a second portion consisted of the substrate trenches 161 and a portion of the encapsulant trench 151 above the substrate trenches 161, which extends through both the substrate 110 and the encapsulant 140.

It could be understood that the scope of this application is not limited to the two-step laser ablation and laser cutting processes described above. In some other embodiments, a single laser cutting process may be employed to remove materials of both the encapsulant 140 and the substrate 110, so as to form the second portion of the trench.

Continuing referring to FIG. 4B, after the substrate trench 161 is formed in the substrate 110, a grounding element 121a is exposed from the substrate trench 161. The grounding element 121a may be connected to other interconnection structures 121 included in the substrate unit 101, and, as further described below, can provide electrical pathways to reduce EMI. In the example shown in FIG. 4B, the grounding element 121a is a conductive layer of the interconnection structures 121 or a portion thereof. It could be understood that the grounding element may be a conductive via of the interconnection structures 121, and may vary in different embodiments.

Referring to FIG. 5, an EMI shield 170 is formed to cover the encapsulant 140 and lateral surfaces of the plurality of substrate units exposed by the substrate trenches.

The EMI shield 170 is formed to shield EMI induced to or generated by the semiconductor device to be formed. In some embodiments, the EMI shield 170 may be formed by spray coating, plating, sputtering, or any other suitable metal deposition process. In some embodiments, the EMI shield 170 may be made of a conductive material such as copper, aluminum, iron, or any other suitable material for electromagnetic interference shielding. The EMI shield 170 may follow the shapes and/or contours of the encapsulant 140, the encapsulant trench 151 and the substrate trench 161. As shown in FIG. 5, the EMI shield 170 may cover the front surface of the encapsulant 140, the lateral surface of the encapsulant 140 exposed by the encapsulant trench 151, and the lateral surface of the substrate 110 exposed by the substrate trench 161. Accordingly, the EMI shield 170 may be electrically connected with the grounding element 121a exposed from the substrate trench 161 (also referring to FIG. 4B).

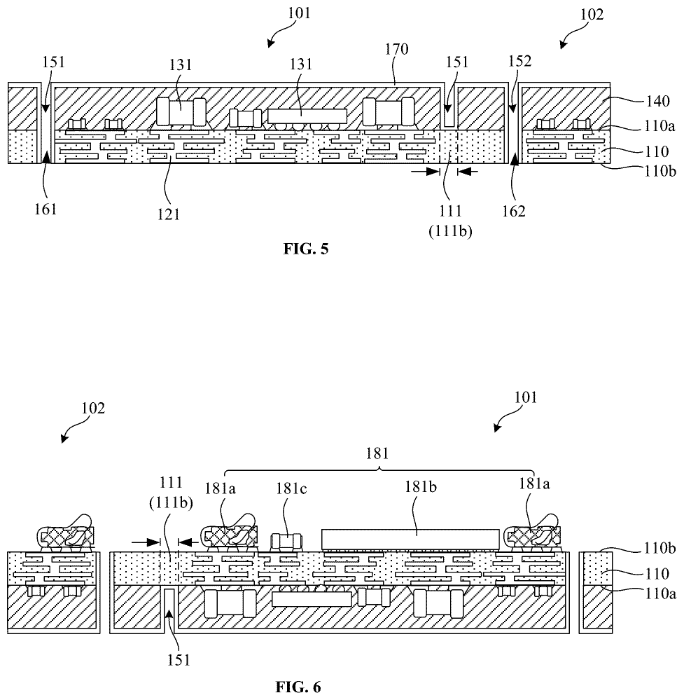

Referring to FIG. 6, the package shown in FIG. 5 is flipped, and a plurality of second electronic components 181 are mounted on the back surface 110b of the substrate 110.

The second electronic components 181 can be mounted on the back surface 110b of the substrate 110 by flip-chip bonding or other suitable surface mounting techniques. For example, solder paste may be deposited or printed onto contact pads where the second electronic components 181 may be surface mounted. Then, the second electronic components 181 may be placed on the back surface 110b of the substrate 110 with terminals of the second electronic components 181 in contact with and over the solder paste. The solder paste may be reflowed to mechanically and electrically couple the second electronic components 181 to the contact pads on the back surface 110b of the substrate 110.

The second electronic components 181 may include any of a variety of types of semiconductor dice, semiconductor packages, or discrete devices. In the example shown in FIG. 6, the second electronic components 181 include one or more clips 181a, one or more connectors 181b, and one or more discrete devices 181c such as resistors, capacitors, inductors, etc. The clips 181a and the connectors 181b can providing interconnect between the semiconductor device to be formed and an external device. The clips 181a and the connectors 181b are widely used in the wearable devices, and can significantly reduce the overall package resistance, compared to Cu wire or Au wire.

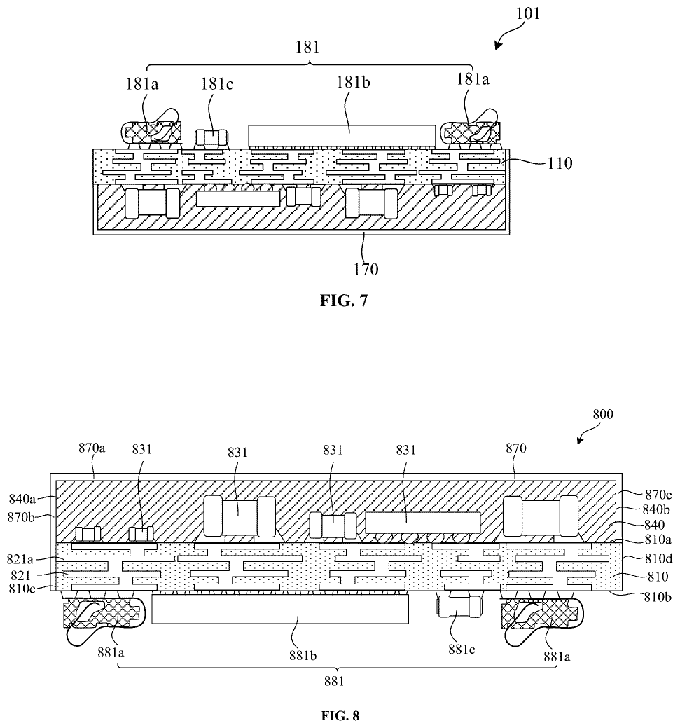

Referring to FIG. 6 and FIG. 7, the substrate 110 is singulated into a plurality of semiconductor devices by removing some portions of the substrate under the first portions of the plurality of trenches. For example, the remaining portions 111b of the singulation area 111 shown in FIG. 6 may be removed to singulate the substrate 110 to form the semiconductor device shown in FIG. 7.

In some embodiments, a punching machine may be used to remove the remaining portions 111b of the singulation area 111. The punching machine may punch on the substrate units respectively to break the remaining portions of the singulation areas, thereby the substrate units can be detached off the substrate strip. However, the present application is not limited thereto. In some other embodiments, a laser cutting process, an etching process, a saw blading, or any other suitable process known in the art can be employed to remove the remaining portions 111b of the singulation area 111.

According to another aspect of the present application, a semiconductor device is provided. Referring to FIG. 8, a cross-sectional view of a semiconductor device 800 is illustrated according to an embodiment of the present application.

As illustrated in FIG. 8, the semiconductor device 800 includes a substrate 810, one or more first electronic components 831, an encapsulant 840 and an EMI shield 870. The substrate 810 may have a front substrate surface 810a and a back substrate surface 810b opposite to the front substrate surface 810a. The first electronic components 831 are mounted on the front substrate surface 810a. The encapsulant 840 is formed on the front substrate surface 810a and encapsulates the first electronic components 831. The EMI shield 870 may have a top portion 870a covering a top surface of the encapsulant 840, a first lateral portion 870b covering a first lateral surface 840a of the encapsulant 840 and a first lateral surface 810c of the substrate 810, and a second lateral portion 870c covering a second lateral surface 840b of the encapsulant 840. The second lateral portion 870c may only cover the second lateral surface 840b of the encapsulant 840, but expose a second lateral surface 810d of the substrate 810.

In some embodiments, the semiconductor device 800 may further include one or more second electronic components 881 mounted on the back substrate surface 810b. In the example shown in FIG. 8, the second electronic elements 881 may include one or more clips 881a, one or more connectors 881b, and one or more discrete devices 881c such as resistors, capacitors, inductors, etc. The clips 881a and the connectors 881b can providing interconnect between the semiconductor device 800 and an external device.

In some embodiments, the semiconductor device 800 further includes a grounding element 810a. The grounding element 810a may be a conductive layer or a conductive via of interconnection structures 821 formed in the substrate 810. The grounding element 810a is exposed from the first lateral surface 810c of the substrate 810, and is electrically connected with the first lateral portion 870b of the EMI shield 870, so as to provide electrical pathways to reduce EMI.

The semiconductor device 800 can be formed using the steps illustrated in FIGS. 1A and 1B to FIGS. 4A and 4B, and FIGS. 5 to 7. Thus, more details about the semiconductor device 800 may refer to the above method embodiments, and will not be elaborated herein.

The discussion herein included numerous illustrative figures that showed various portions of a semiconductor device and a method for making the same. For illustrative clarity, such figures did not show all aspects of each example device. Any of the example devices and/or methods provided herein may share any or all characteristics with any or all other devices and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for making a semiconductor device, comprising:
providing a package comprising:
a substrate having a front substrate surface and a back substrate surface opposite to the front substrate surface, wherein the substrate comprises a plurality of singulation areas separating the substrate into a plurality substrate units;
a plurality of first electronic components mounted on the front substrate surface and within the plurality substrate units, respectively; and
an encapsulant formed on the front substrate surface and encapsulating the plurality of first electronic components;
forming a plurality of trenches at the plurality of singulation areas, respectively, wherein each of the plurality of trenches has a first portion extending through the encapsulant and a second portion extending through the encapsulant and the substrate; and
forming an electromagnetic interference (EMI) shield to cover the encapsulant and lateral surfaces of the plurality of substrate units exposed by the second portions of the plurality of trenches.

2. The method of claim 1, wherein forming the plurality of trenches at the plurality of singulation areas comprises:
removing a portion of the encapsulant at the plurality of singulation areas to form the first portion of the trench and an upper portion of the second portion of the trench; and
removing a first portion of the substrate under the upper portion of the second portion of the trench to form a lower portion of the second portion of the trench.

3. The method of claim 1, further comprising:
mounting a plurality of second electronic components on the back substrate surface and within the plurality substrate units, respectively.

4. The method of claim 3, wherein the plurality of second electronic components comprise a clip or a connector for providing interconnect between the semiconductor device and an external device.

5. The method of claim 1, further comprising:
singulating the substrate into a plurality of semiconductor devices by removing a second portion of the substrate under the first portions of the plurality of trenches.

6. The method of claim 1, wherein each of the plurality of singulation areas forms a closed track enclosing a respective substrate unit.

7. The method of claim 1, wherein the plurality of substrate units are arranged in a row or in an array.

8. The method of claim 1, wherein each of the plurality substrate units comprises a grounding element exposed by the second portion of a respective trench, and the EMI shield is electrically connected to the grounding element.

9. A semiconductor device, comprising:
a substrate having a front substrate surface and a back substrate surface opposite to the front substrate surface;
a first electronic component mounted on the front substrate surface;
an encapsulant formed on the front substrate surface and encapsulating the first electronic component; and
an electromagnetic interference (EMI) shield having a top portion covering a top surface of the encapsulant, a first lateral portion covering a first lateral surface of the encapsulant and a first lateral surface of the substrate, and a second lateral portion covering a second lateral surface of the encapsulant.

10. The semiconductor device of claim 9, further comprising:
a second electronic component mounted on the back substrate surface.

11. The semiconductor device of claim 10, wherein the second electronic element comprises a clip or a connector for providing interconnect between the semiconductor device and an external device.

12. The semiconductor device of claim 9, wherein the substrate comprises a grounding element exposed from the first lateral surface of the substrate, and the first lateral portion of the EMI shield is electrically connected with the grounding element.

13. The semiconductor device of claim 9, wherein the substrate further comprises a second lateral surface exposed from the EMI shield.
